(19) United States
(12) Patent Application Publication
(10) Pub. No.: US 2015/0129010 A1
(43) Pub. Date: May 14, 2015

(54) THERMOELECTRIC DEVICE AND FABRICATING METHOD THEREOF

(71) Applicant: Electronics and Telecommunications Research Institute, Daejeon (KR)

(72) Inventors: Dong Suk JUN, Daejeon (KR); Moon Gyu JANG, Daejeon (KR); Soojung KIM, Incheon (KR)

(73) Assignee: Electronics and Telecommunications Research Institute, Daejeon (KR)

(21) Appl. No.: 14/290,204

(22) Filed: May 29, 2014

(30) Foreign Application Priority Data
Nov. 8, 2013 (KR) 10-2013-0135488

(51) Int. Cl. H01L 35/10; H01L 35/34; H01L 35/28; H01L 35/14

(52) U.S. Cl. CPC H01L 35/10; H01L 35/14; H01L 35/34; H01L 35/28
USPC 136/203; 438/54

(57) ABSTRACT

Provided is a thermoelectric device. The thermoelectric device includes a substrate; first and second electrodes disposed at one side of the substrate, wherein the first and second electrodes are apart from each other; a common electrode formed on the other side of the substrate, wherein the common electrode is separated from the first and second electrodes; first and second legs connecting the common electrode to the first electrode, and the common electrode to the second electrode, respectively; and first and second barrier patterns covering the first and second legs and the substrate between the common electrode and the first electrode and between the common electrode and the second electrode, wherein the first and second barrier patterns prevents the short between the first and second legs and the common electrode and between the first and second legs and the first and second electrodes.

### CROSS-REFERENCE TO RELATED APPLICATIONS

This U.S. non-provisional patent application claims priority under 35 U.S.C. §119 of Korean Patent Application No. 10-2013-0135488, filed on Nov. 8, 2013, the entire contents of which are hereby incorporated by reference.

### BACKGROUND OF THE INVENTION

With the recent high interest in clean energy, a research on a thermoelectric device is being actively performed. The thermoelectric device may change thermal energy to electric energy or vice versa to generate a temperature difference.

A ZT value (thermoelectric figure of merit value) is used as an index estimating the thermoelectric efficiency of the thermoelectric device. The ZT value is in proportion to a square of the Seebeck coefficient and electrical conductivity and is in inverse proportion to thermal conductivity. The ZT value may be determined as an inherent characteristic of a corresponding material. In case of metal, the Seebeck coefficient is very low as several uV/K. The electrical conductivity and the thermal conductivity have a proportional relationship by Wiedemann-Franz Law. It means that in case of metal, heat transfer is mainly performed by free charges of electrons or holes. Thus, in case of metal, it may be very difficult to implement low thermal conductivity that is needed in the thermoelectric device. Moreover, enhancing the ZT value by using metal is almost impossible.

However, in case of a semiconductor, since it is possible to freely adjust the density of a charge, heat transfer by free charges may be properly controlled. The main heat transfer medium of the semiconductor is a lattice, and quantizing lattice vibration and describing it as a wave is phonon. Thus, it is possible to sharply decrease thermal conductivity by properly adjusting the density of free charges in the semiconductor, minimizing heat transfer due to them, and inhibiting the propagation of the phonon.

Meanwhile, as materials for the fabricated thermoelectric device, Bi2Te3 has been used at room temperature and SiGe has been used at high temperature.

The ZT value of Bi2Te3 may be 0.7 at room temperature and 0.9 that is a maximum value at 120° C. and the ZT value of SiGe may be about 0.1 at room temperature and 0.9 that is a maximum value at 900° C.

Research based on silicon that is a basic material of a semiconductor industry has also been interested. The silicon has very high thermal conductivity as 150 W/m·K and the ZT value of 0.01 and therefore, it has been appreciated that it is difficult to use as the thermoelectric device. However, it is reported that in case of a silicon nanowire grown through chemical vapor deposition (CVD), the thermal conductivity may be reduced to 0.01 times or less and therefore, the ZT value approaches 1.

### SUMMARY OF THE INVENTION

The present invention provides a thermoelectric device and a fabricating method thereof that may increase the electrical conductivity between electrodes and decrease thermal conductivity therebetween.

The present invention also provides a thermoelectric device and a fabricating method thereof that may prevent the short of legs connected to electrodes.

Embodiments of the inventive concept provide thermoelectric devices include a substrate; first and second electrodes disposed at one side of the substrate, wherein the first and second electrodes are apart from each other; a common electrode formed on the other side of the substrate, wherein the common electrode is separated from the first and second electrodes; first and second legs formed on the substrate, wherein the first legs connect the common electrode to the first electrode, and the second legs connect the common electrode to the second electrode; and first and second barrier patterns covering the first and second legs and the substrate between the common electrode and the first electrode and between the common electrode and the second electrode, wherein the first and second barrier patterns prevents the short between the first and second legs and the common electrode and between the first and second legs and the first and second electrodes.

In some embodiments, each of the first legs may include a first bonding portion connected to the first electrode and a second bonding portion connected to the common electrode, and each of the second legs may include a third bonding portion connected to the second electrode and a fourth bonding portion connected to the common electrode.

In other embodiments, the first barrier pattern may include a first edge barrier pattern covering the first legs of the first bonding portion and a second edge barrier pattern covering the first legs of the second bonding portion, and the second barrier pattern may include a third edge barrier pattern covering the second legs of the third bonding portion and a fourth edge barrier pattern covering the second legs of the fourth bonding portion.

In still other embodiments, the first barrier pattern may include first coating barrier patterns that are extended from the first bonding portion to the second bonding portion along the first legs and individually cover the first legs, and the second barrier pattern may include second coating barrier patterns that are extended from the third bonding portion to the fourth bonding portion along the second legs and individually cover the second legs.

In even other embodiments, the first barrier pattern may include first coating barrier patterns that are extended from the first bonding portion to the second bonding portion along the first legs and partially cover the first legs in at least one of a first group, and the second barrier pattern may include second coating barrier patterns that are extended from the third bonding portion to the fourth bonding portion along the second legs and partially cover the second legs in at least one of a second group.

In yet other embodiments, the first and second legs may have the same thickness as the first and second barrier patterns.

In further embodiments, the first and second legs may include silicon nano wires.

In still further embodiments, the first and second legs may respectively have first and second air gaps over the substrate, the air gaps enabling the first and second legs to be apart from the substrate.

In even further embodiments, the first barrier pattern and the second barrier pattern may include a rare metal and a rare-earth metal, respectively.

In yet further embodiments, the first barrier pattern and the second barrier pattern may include platinum and erbium, respectively.

In much further embodiments, the thermoelectric device may further include buffer layers between the substrate and the first electrode, between the substrate and the second electrode, and between the substrate and the common electrode.

In other embodiments of the inventive concept, methods of fabricating a thermoelectric device include providing a substrate; forming first and second legs parallel to the substrate; forming first and second barrier patterns on the first and second legs respectively; and forming first and second electrodes on the substrate of one side of the first and second legs, and a common electrode on the substrate of the other side of the first and second legs, wherein the first and second barrier patterns prevent the short between the first and second legs and the common electrode and between the first and second legs and the first and second electrodes.

In some embodiments, the providing of the substrate may include forming a buffer layer on the substrate; and forming a silicon layer on the buffer layer, wherein the first and second legs may be formed by patterning the silicon layer.

In other embodiments, the method may further include removing the buffer layer under the first and second legs to form first and second air gaps between the first and second legs and the substrate.

In still other embodiments, the forming of the first and second barrier patterns may include forming a rare metal and a rare-earth meal on the first and second legs; and thermally treating the rare metal and the rare-earth metal.

In even other embodiments, treating the rare metal and the rare-earth metal may be performed at 600° C. or higher.

In yet other embodiments, the rare metal and the rare-earth metal may respectively include platinum and erbium formed by using metal deposition.

In further embodiments, the rare metal and the rare-earth metal may be formed by using printing or dropping.

In still further embodiments, the first barrier pattern may include at least one of a first edge barrier pattern, a second edge barrier pattern, a first coating barrier pattern, and a first block barrier pattern, and the second barrier pattern may include at least one of a third edge barrier pattern, a fourth edge barrier pattern, a second coating barrier pattern, and a second block barrier pattern.

In even further embodiments, the first and second barrier patterns may be formed to have the same thickness as the first and second legs.

### BRIEF DESCRIPTION OF THE DRAWINGS

Various embodiments of the inventive concept are described below in more detail with reference to the accompanying drawings. The effects and features of the present invention, and implementation methods thereof will be clarified through following embodiments described with reference to the accompanying drawings. However, the present invention is not limited embodiments to be described below but may be implemented in other forms. Rather, these embodiments are provided so that this disclosure will be thorough and complete, and will fully convey the scope of the present invention to those skilled in the art, and furthermore, the present invention is only defined by scopes of claims. The same reference numerals throughout the disclosure refer to the same components.

The terms used herein are only for explaining specific embodiments while not limiting the present invention. The terms of a singular form may include plural forms unless referred to the contrary. The terms used herein “includes”, “comprises”, “including” and/or “comprising” do not exclude the presence or addition of one or more components, steps, operations and/or elements other than the components, steps, operations and/or elements that are mentioned. Furthermore, since the following description present an exemplary embodiment, the reference numerals presented according to the order of the description is not limited thereto.

The accompanying drawings are included to provide a further understanding of the present invention, and are incorporated in and constitute a part of this specification. The drawings illustrate exemplary embodiments of the inventive concept and, together with the description, serve to explain principles of the present invention. In the drawings:

FIG. 1 is a perspective view of a thermoelectric device according to an embodiment of the inventive concept;

FIG. 2 is a plane view of FIG. 1;

FIG. 3 is a plane view of a thermoelectric device according to a first application of the embodiment of the inventive concept;

FIG. 4 is a plane view of a thermoelectric device according to a second application of the embodiment of the inventive concept;

FIG. 5 is a plane view of a thermoelectric device according to a third application of the embodiment of the inventive concept; and

FIGS. 6 to 9 are perspective views of a method of fabricating a thermoelectric device according to an embodiment of the inventive concept based on FIG. 1.

### DETAILED DESCRIPTION OF PREFERRED EMBODIMENTS

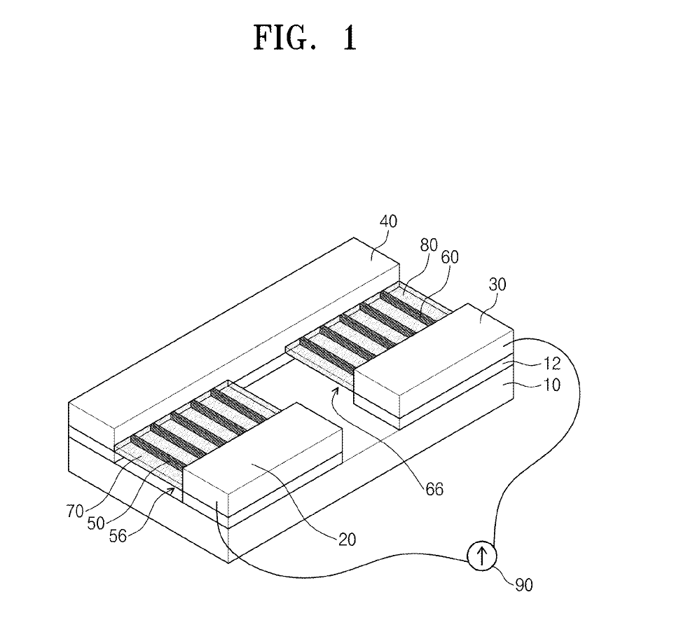

FIG. 1 is a perspective view of a thermoelectric device according to an embodiment of the inventive concept. FIG. 2 is a plane view of FIG. 1.

Referring to FIGS. 1 and 2, the thermoelectric device of the embodiment of the inventive concept may include a substrate 10, a buffer layer 12, a first electrode 20, a second electrode 30, a common electrode 40, first legs 50, second legs 60, a first barrier pattern 70, and a second barrier pattern 80.

The substrate 10 may be a silicon substrate, a glass substrate, a plastic substrate, a metal substrate, a silicon on insulator (SOI) substrate, or a laminated substrate formed by combinations thereof.

The buffer layer 12 may be disposed on one side of the substrate 10 and the other side thereof. The buffer layer 12 may include silicon nitride (SiN) or silicon oxide (SiO2).

The first and the second electrodes 20 and 30 may be disposed on the buffer layer 12 on one side of the substrate 10. The first and the second electrodes 20 and 30 may be separated from each other. The buffer layer 12 may be disposed between the first electrode 20 and the substrate 10. Moreover, the buffer layer 12 may be disposed between the substrate 10 and the second electrode 30. The first and the second electrodes 20 and 30 may include at least one of metals such as aluminum (Al), copper (Cu), tungsten (W), titanium (Ti), silver (Ag), gold (Au), platinum (Pt), nickel (Ni), carbon (C), molybdenum (Mo), tantalum (Ta), iridium (Ir), ruthenium (Ru), zinc (Zn), tin (Sn) and indium (In). The first and the second electrodes 20 and 30 may be low temperature portions that are provided in a low-temperature environment. An ammeter 90 may be connected between the first and the second electrodes 20 and 30.

The common electrode 40 may be disposed on the other side of the substrate 10. The buffer layer 12 may be disposed between the common electrode 40 and the substrate 10. The common electrodes 40 may be apart from the first and the second electrodes 20 and 30. The common electrodes 40 may include at least one of metals such as aluminum (Al), copper (Cu), tungsten (W), titanium (Ti), silver (Ag), gold (Au), platinum (Pt), nickel (Ni), carbon (C), molybdenum (Mo), tantalum (Ta), iridium (Ir), ruthenium (Ru), zinc (Zn), tin (Sn) and indium (In). The common electrodes 40 may be a high-temperature portion that is provided for a high-temperature environment having a higher temperature than the first and the second electrodes 20 and 30.

The first legs 50 may connect the first electrode 20 to the common electrode 40. The first legs 50 may have first air gaps 56 over the substrate 10, the air gaps corresponding to the height of the buffer layer 12. The first legs 50 may easily transfer phonons between the first electrode 20 and the common electrode 40. According to the embodiment of the inventive concept, the first legs 50 may include a nano structure. The first legs 50 having the nano structure may have circular, triangular, quadrilateral, pentagonal, or hexagonal sectional shapes. For example, the first legs 50 may include silicide nano wires or silicon nano wires having a 1D nano structure. The first legs 50 may be doped with a first conductive impurity. The first conductive impurity may include a P type dopant such as boron, aluminum, gallium, or indium.

The second legs 60 may connect the third electrode 30 to the common electrode 40. The second legs 60 may have a second air gap 66 over the substrate 10, the air gap corresponding to the height of the buffer layer 12. The second legs 60 may be apart from the first legs 50. The second legs 60 may easily transfer phonons between the second electrode 30 and the common electrode 40. The second legs 60 may include silicon nano wires or silicide nano wires. The second legs 60 may be doped with a second conductive impurity. The second conductive impurity may include an N type dopant such as arsenic, phosphorous, nitride, or antimonium.

On the other hand, the common electrode 40 may absorb ambient heat. The absorbed heat may be externally emitted through the first and the second legs 50 and 60 and the first and the second electrodes 20 and 30. To be bonded to an external wire, the first and the second electrodes 20 and 30 and the common electrode 40 may be thicker than the first and the second legs 50 and 60 and the first and the second bather patterns 70 and 80.

When there is a potential difference between the first and the second electrodes 20 and 30, a current may flow. The ammeter 90 may detect the currents between the first and the second electrodes 20 and 30. In this case, the currents may flow through the first and the second barrier patterns 70 and 80.

The first and the second barrier patterns 70 and 80 may be respectively disposed on the substrate 10 between the first and the second electrodes 20 and 30 and the common electrode 40. The first and the second barrier patterns 70 and 80 may respectively cover the first and the second legs 50 and 60. According to an embodiment of the inventive concept, the first and the second barrier patterns 70 and 80 may have the same as or smaller thickness than those of the first and the second legs 50 and 60. The first and the second barrier patterns 70 and 80 may be apart from each other. The first and the second barrier patterns 70 and 80 may include a rare-earth metal such as erbium (Er), europium (Eu) or samarium (Sm). Moreover, the first and the second barrier patterns 70 and 80 may include a rare metal such as magnesium (Mg), platinum (Pt), Ytterbium (Yb), nickel (Ni), cobalt (Co), or titanium (Ti). For example, the first barrier pattern 70 may include platinum. Platinum may maximize the Seebeck coefficient of a thermoelectric device. The second barrier pattern 80 may include erbium.

The first barrier pattern 70 may protect the first legs 50. According to the embodiment of the inventive concept, the first barrier pattern 70 may prevent the electrical short and/or breaking between the first bonding portion 52 and the second bonding portion 54 of the first legs 50. The first legs 50 are connected to the first electrode 20 at the first bonding portion 52. The first legs 50 are connected to the common electrode 40 at the second bonding portion 54. When currents flow to the first legs 50, the first legs 50 may be vulnerable to electrical short and/or breaking due to heat emission resulting from the bonding resistance at the first bonding portion 52 and the second bonding portion 54. The first barrier pattern 70 may increase the electrical conductivity between the first electrode 20 and the common electrode 40. The first barrier pattern 70 may play a role of scattering charges gathering on the first bonding portion 52 and the second bonding portion 54 of the first legs 50. Moreover, the first barrier pattern 70 may inhibit the phonon propagation between the first electrode 20 and the common electrode 40. The first barrier pattern 70 may decrease the thermal conductivity between the first electrode 20 and the common electrode 40. In particular, the thermal conductivity may decrease by phonon dispersion on the first barrier pattern 70 and the first legs 50.

Likewise, the second barrier pattern 80 may protect the second legs 60. According to the embodiment of the inventive concept, the second barrier pattern 80 may prevent the electrical short and/or breaking between the third bonding portion 62 and the fourth bonding portion 64 of the second legs 60. The second legs 60 are connected to the second electrode 30 at the third bonding portion 62 The second legs 60 are connected to the common electrode 40 at the fourth bonding portion 64 The second barrier pattern 80 may increase the electrical conductivity between the second electrode 30 to the common electrode 40. The second barrier pattern 80 may prevent charge gathering on the third bonding portion 62 and the fourth bonding portion 64. The second bather pattern 80 may inhibit the phonon propagation between the second electrode 30 and the common electrode 40 and decrease thermal conductivity therebetween.

Applications depending on the shapes of the first barrier pattern 70 and the second barrier pattern 80 are described below.

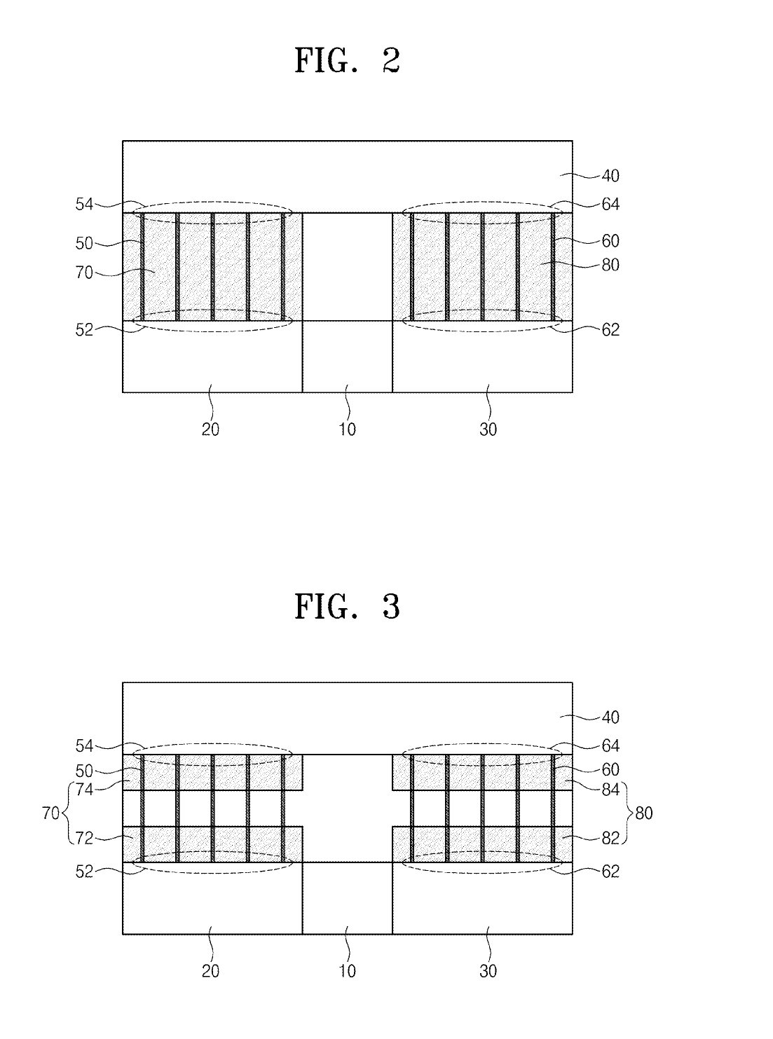

FIG. 3 is a plane view of a thermoelectric device according to a first application of the embodiment of the inventive concept.

Referring to FIG. 3, the thermoelectric device according to the first application of the embodiment of the inventive concept may include the first barrier pattern 70 and the second barrier pattern 80. The first barrier pattern 70 may protect a first edge barrier pattern 72 and a second edge barrier pattern 74. The first edge barrier pattern 72 may cover the first legs 50 of the first bonding portion 52. The second edge barrier pattern 74 may cover the first legs 50 of the second bonding portion 54. The first edge barrier pattern 72 and the second edge barrier pattern 74 may prevent the electrical short and/or breaking of the first legs 50 at the first bonding portion 52 and the second bonding portion 54.

The second barrier pattern 80 may include a third edge barrier pattern 82 and a fourth edge barrier pattern 84. The third edge barrier pattern 82 may cover the second legs 60 of the third bonding portion 62. The fourth edge barrier pattern 84 may cover the second legs 60 of the fourth bonding portion 64. The third edge barrier pattern 82 and the fourth edge barrier pattern 84 may prevent the electrical short and/or breaking of the second legs 60 at the third bonding portion 62 and the fourth bonding portion 64.

According to the first application, the first barrier 70 of the embodiment includes the first edge barrier pattern 72 and the second edge bather pattern 74, and the second barrier pattern 80 includes the third edge barrier pattern 82 and the fourth edge barrier pattern 84.

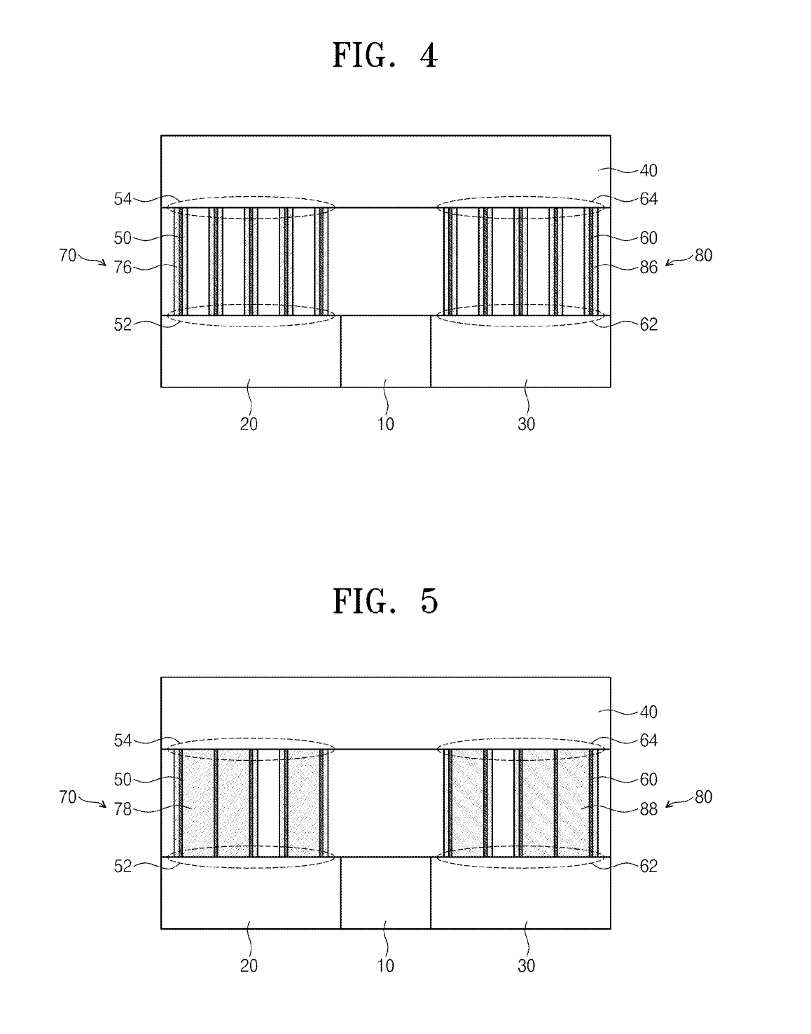

FIG. 4 is a plane view of a thermoelectric device according to a second application of the embodiment of the inventive concept.

Referring to FIG. 4, the thermoelectric device according to the second application of the embodiment of the inventive concept may include the first coating barrier patterns 76 of the first barrier pattern 70 and the second coating barrier patterns 86 of the second barrier pattern 80. The first coating barrier patterns 76 may be separated from one another and individually cover the first legs 50. The first coating barrier patterns 76 may be extended from the first bonding portion 52 to the second bonding portion 54 along the first legs 50.

The second coating barrier patterns 86 may be separated from one another and individually cover the second legs 60. The second coating barrier patterns 86 may be extended from the third bonding portion 62 to the fourth bonding portion 64 along the first legs 60.

According to the second application, the first barrier pattern 70 and the second barrier pattern 80 of the embodiment are respectively replaced with the first coating barrier patterns 76 and the second coating barrier patterns 86.

FIG. 5 is a plane view of a thermoelectric device according to a third application of the embodiment of the inventive concept.

Referring to FIG. 5, the thermoelectric device according to the third application of the embodiment of the inventive concept may include first block barrier patterns 78 of the first barrier pattern 70 and second block barrier patterns 88 of the second barrier pattern 80. The first block barrier patterns 78 may partially cover the first legs 50 in at least one of a first group. The first block barrier patterns 78 may be extended from the first bonding portion 52 to the second bonding portion 54 along the first legs 50.

The second block barrier patterns 88 may partially cover the second legs 60 in at least one of a second group. The second block barrier patterns 88 may be extended from the third bonding portion 62 to the fourth bonding portion 64 along the second legs 60.

According to the third application, the first barrier pattern 70 and the second barrier pattern 80 of the embodiment are respectively replaced with the first block barrier patterns 78 and the second block barrier patterns 88.

Methods of fabricating such thermoelectric elements according to the embodiment of the first to the third applications of the embodiment of the inventive concept are as follows.

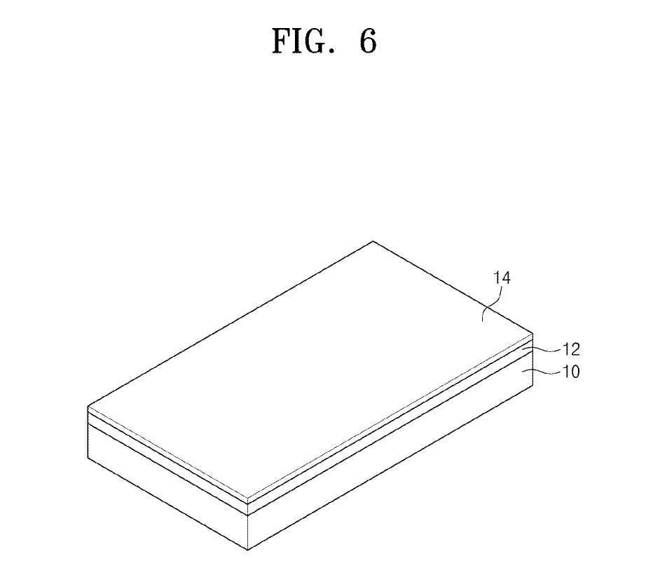

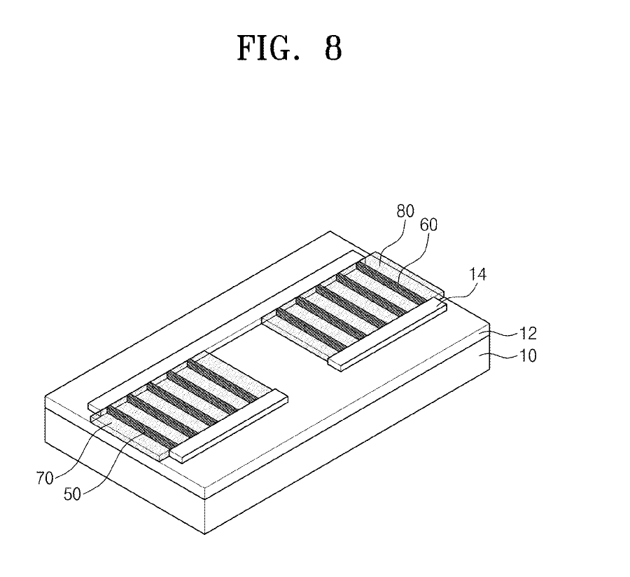

FIGS. 6 to 9 are perspective views of a method of fabricating a thermoelectric device according to an embodiment of the inventive concept based on FIG. 1.

Referring to FIG. 6, the buffer layer 12 and the silicon layer 14 are formed on the substrate 10. The buffer layer 12 may include a silicon nitride layer or a silicon oxide layer formed by using chemical vapor deposition. The silicon layer 14 may include single crystal silicon or poly-silicon. According to the embodiment of the inventive concept, the substrate 10, the buffer layer 12, and the silicon layer 14 may include a silicon oxide insulator (SOI) substrate.

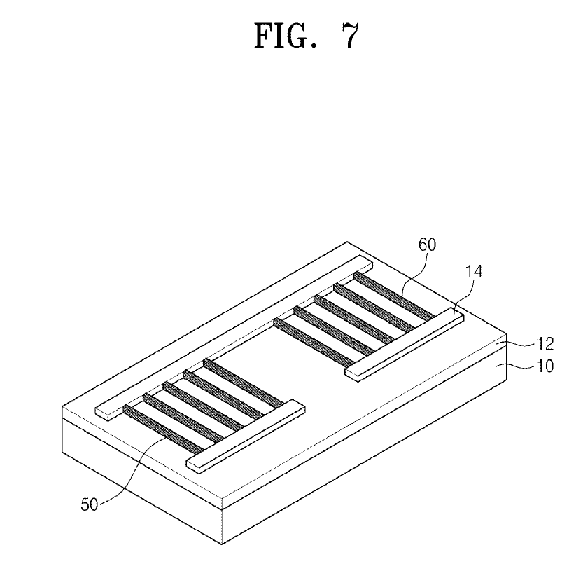

Referring to FIG. 7, the silicon layer 14 is patterned to form the first legs 50 and the second legs 60 on the buffer layer 12. The first legs 50 and the second legs 60 may include a silicon nano wire that is formed by using a photolithography process, an etching process, and a thermal treatment process.

Referring to FIGS. 1 to 5 and 8, the first bather pattern 70 and the second barrier pattern 80 are formed on the first legs 50 and the second legs 60. The first barrier pattern 70 is formed on the first legs 50, and the second barrier pattern 80 is formed on the second legs 60. According to the embodiment of the inventive concept, the first barrier pattern 70 and the second barrier pattern 80 may respectively include a rare metal and a rare-earth metal. For example, the first barrier pattern 70 may include platinum that belongs to the rare metal. Platinum may maximize the Seebeck coefficient. The second barrier pattern 80 may include erbium that belongs to the rare-earth metal. The formation of the first barrier pattern 70 and the second barrier pattern 80 may include a metal deposition process, photolithography and etching techniques. Moreover, the formation of the first barrier pattern 70 and the second barrier pattern 80 may include a printing process or a dropping process.

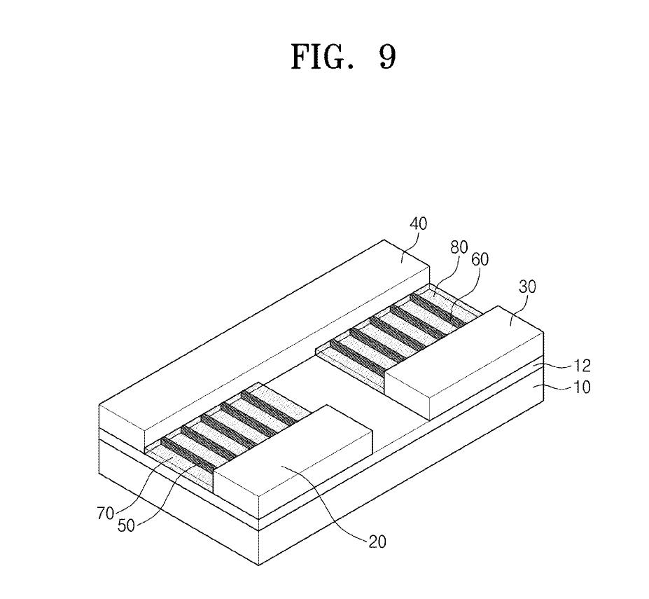

The first barrier pattern 70 and the second barrier patterns 80 may be formed to have the same as or smaller thickness than those of the first legs 50 and the second legs 60. The first legs 50 and the second legs 60 may be formed as silicide nano wires by the thermal treatment processes of the first barrier pattern 70 and the second barrier pattern 80. The thermal treatment processes may be performed at 600 C or higher. The first and the second barrier patterns 70 and 80 on the first legs 50 and the second legs 60 may permeate the first and the second legs 50 and 60. In this example, the first barrier pattern 70 may include at least one of the first edge barrier pattern 72, the second edge barrier pattern 74, the first coating barrier patterns 76 and the first block barrier patterns 78. Moreover, the second barrier pattern 80 may include any one of the third edge bather pattern 82, the fourth edge bather pattern 84, the second coating barrier patterns 76, and the second block barrier patterns 88. Referring to FIG. 9, the first electrode 20 and the second electrode 30 are respectively formed at one sides of the first legs 50 and the second legs 60, and the common electrode 40 is formed at the other sides of the first legs 50 and the second legs 60. The first and the second electrodes 20 and 30 may be separated from each other. The first and the second electrodes 20 and 30 and the common electrode 40 may be formed by using a metal deposition process, a photolithography process and an etching process. To be bonded to an external wire, the first and the second electrodes 20 and 30 may be formed to be thicker than the first and the second legs 50 and 60 and the first and the second barrier patterns 70 and 80.

Referring back to FIG. 1, the buffer layer 12 under the first legs 50 and the second legs 60 is removed. The buffer layer 12 may be removed by using isotropic wet etching. The buffer layer 12 may remain on the substrate 10 under the first electrode 20, the second electrode, and the common electrode 10. The first legs 50 and the second legs 60 may have the first and the second air gaps 56 and 66 over the substrate 10. The buffer layer 12 may be etched more quickly under the first legs 50 and the second legs 60 than under the first electrode 20, the second electrode 30, and the common electrode 40.

As described above, the thermoelectric devices according to embodiments of the inventive concept may include a first barrier pattern covering the first legs between the common electrode and the first electrode and a second barrier pattern covering the second legs between the common electrode and the second electrode. The first barrier pattern may increase the electrical conductivity between the common electrode and the first electrode and decrease the thermal conductivity therebetween. The second barrier pattern may increase the electrical conductivity between the common electrode and the second electrode and decrease the thermal conductivity therebetween. Moreover, the first barrier pattern and the second barrier pattern may prevent the short and/or breaking between the first legs and the second legs.

While embodiments of the inventive concept are described with reference to the accompanying drawings, a person skilled in the art will be able to understand that the present invention may be practiced as other particular forms without changing essential characteristics. Therefore, embodiments described above should be understood as illustrative and not limitative in every aspect.

What is claimed is:

1. A thermoelectric device comprising:
a substrate;
first and second electrodes disposed at one side of the substrate, wherein the first and second electrodes are apart from each other;
a common electrode formed on the other side of the substrate, wherein the common electrode is separated from the first and second electrodes;
first and second legs formed on the substrate, wherein the first legs connect the common electrode to the first electrode, and the second legs connect the common electrode to the second electrode; and
first and second barrier patterns covering the first and second legs and the substrate between the common electrode and the first electrode and between the common electrode and the second electrode, wherein the first and second barrier patterns prevents the short between the first and second legs and the common electrode and between the first and second legs and the first and second electrodes.

2. The thermoelectric device of claim 1, wherein each of the first legs comprises a first bonding portion connected to the first electrode and a second bonding portion connected to the common electrode, and
each of the second legs comprises a third bonding portion connected to the second electrode and a fourth bonding portion connected to the common electrode.

3. The thermoelectric device of claim 2, wherein the first barrier pattern comprises a first edge barrier pattern covering the first legs of the first bonding portion and a second edge barrier pattern covering the first legs of the second bonding portion, and
the second barrier pattern comprises a third edge barrier pattern covering the second legs of the third bonding portion and a fourth edge barrier pattern covering the second legs of the fourth bonding portion.

4. The thermoelectric device of claim 2, wherein the first barrier pattern comprises first coating barrier patterns that are extended from the first bonding portion to the second bonding portion along the first legs and individually cover the first legs, and
the second barrier pattern comprises second coating barrier patterns that are extended from the third bonding portion to the fourth bonding portion along the second legs and individually cover the second legs.

5. The thermoelectric device of claim 2, wherein the first barrier pattern comprises first coating barrier patterns that are extended from the first bonding portion to the second bonding portion along the first legs and partially cover the first legs in at least one of a first group, and
the second barrier pattern comprises second coating barrier patterns that are extended from the third bonding portion to the fourth bonding portion along the second legs and partially cover the second legs in at least one of a second group.

6. The thermoelectric device of claim 1, wherein the first and second legs have the same thickness as the first and second barrier patterns.

7. The thermoelectric device of claim 1, wherein the first and second legs comprise silicon nano wires.

8. The thermoelectric device of claim 1, wherein the first and second legs respectively have first and second air gaps over the substrate, the air gaps enabling the first and second legs to be apart from the substrate.

9. The thermoelectric device of claim 1, wherein the first barrier pattern and the second barrier patter comprise a rare metal and a rare-earth metal, respectively.

10. The thermoelectric device of claim 1, wherein the first barrier pattern and the second barrier patter comprise platinum and erbium, respectively.

11. The thermoelectric device of claim 1, further comprising buffer layers between the substrate and the first electrode, between the substrate and the second electrode, and between the substrate and the common electrode.

12. A method of fabricating a thermoelectric device, the method comprising:
providing a substrate;
forming first and second legs parallel to the substrate;
forming first and second barrier patterns on the first and second legs respectively; and
forming first and second electrodes on the substrate of one side of the first and second legs, and a common electrode on the substrate of the other side of the first and second legs,
wherein the first and second barrier patterns prevent the short between the first and second legs and the common electrode and between the first and second legs and the first and second electrodes.

13. The method of claim 12, wherein the providing of the substrate comprises:
forming a buffer layer on the substrate; and
forming a silicon layer on the buffer layer,
wherein the first and second legs are formed by patterning the silicon layer.

14. The method of claim 13, further comprising removing the buffer layer under the first and second legs to form first and second air gaps between the first and second legs and the substrate.

15. The method of claim 12, wherein the forming of the first and second barrier patterns comprises:
forming a rare metal and a rare-earth meal on the first and second legs; and
thermally treating the rare metal and the rare-earth metal.

16. The method of claim 15, wherein treating the rare metal and the rare-earth metal is performed at 600° C. or higher.

17. The method of claim 15, wherein the rare metal and the rare-earth metal respectively comprises platinum and erbium formed by using metal deposition.

18. The method of claim 15, wherein the rare metal and the rare-earth metal are formed by using printing or dropping.

19. The method of claim 12, wherein the first barrier pattern comprises at least one of a first edge barrier pattern, a second edge barrier pattern, a first coating barrier pattern, and a first block barrier pattern, and
the second barrier pattern comprises at least one of a third edge barrier pattern, a fourth edge barrier pattern, a second coating barrier pattern, and a second block barrier pattern.

20. The thermoelectric device of claim 12, wherein the first and second barrier patterns are formed to have the same thickness as the first and second legs.
